(19) United States
(12) Patent Application Publication
(10) Pub. No.: US 2006/0081942 A1
(43) Pub. Date: Apr. 20, 2006

(54) Semiconductor device and manufacturing method therefor

(76) Inventor: Tomohiro Saito, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/043,115

(22) Filed: Jan. 27, 2005

(30) Foreign Application Priority Data
Oct. 19, 2004 (JP) 2004-304584

(51) Int. Cl. H01L 29/76

(52) U.S. Cl. 257/388

(57) ABSTRACT

A semiconductor device, comprising: a conductive layer which includes a metal and is formed on a silicon substrate via an insulation layer, the insulation layer being formed by implanting an impurity ion and having a stress changing region with stress different from that of the other region.

### CROSS REFERENCE TO RELATED APPLICATIONS

This application is based upon and claims the benefit of priority from the prior Japanese Patent Application No. 2004-304584, filed on Oct. 19, 2004, the entire contents of which are incorporated herein by reference.

### BACKGROUND OF THE INVENTION

1. Field of the Invention

The present invention relates to a semiconductor device with a conductive layer formed on a silicon substrate via an insulation layer, and a method of manufacturing the semiconductor device.

2. Related Art

Along the progress of miniaturization of semiconductor integrated circuits, gate electrodes made of metal materials having no gate depletion layer has come to be used in place of conventional polysilicon electrodes. In order to improve electric performance of a silicon semiconductor, a channel part is deformed by applying stress to improve mobility, thereby increasing a drive current of a transistor (Japanese Patent Application No. 2002-93921).

The gate electrode made of a metal material essentially has compressive stress or tensile stress, and mobility of either a PMOS transistor or an NMOS transistor can be improved. This may lead to lower the mobility of the transistor different from the transistor of which mobility is improved.

### SUMMARY OF THE INVENTION

The present invention provides a semiconductor device of which mobility can be improved regardless of conduction types of transistors formed on a silicon substrate, and a method of manufacturing the semiconductor device.

A semiconductor device according to one embodiment of the present invention, comprising:

a conductive layer which includes a metal and is formed on a silicon substrate via an insulation layer, said insulation layer being formed by implanting an impurity ion and having a stress changing region with stress different from that of the other region.

Furthermore, a semiconductor device according to one embodiment of the present invention, comprising:

an insulation layer formed on a silicon substrate;

a first conductive layer formed on said insulation layer; and

a second conductive layer which includes a metal and is formed on said first conductive layer,

wherein said second conductive layer has a stress changing region which is formed by implanting an impurity ion and has stress different from that of the other region.

Furthermore, a method of fabricating a semiconductor device, comprising:

forming a conductive layer including a metal on a silicon substrate via an insulation layer; and

forming a stress changing region with stress different from that of the other region by implanting an impurity ion to a portion of said conductive layer.

### BRIEF DESCRIPTION OF THE DRAWINGS

FIG. 1 is a cross-sectional diagram showing a cross-sectional configuration of a semiconductor device according to a first embodiment of the present invention.

FIG. 2 is a cross-sectional diagram showing one example of a process of manufacturing the semiconductor device shown in FIG. 1.

FIG. 3 is a cross-sectional diagram subsequent to FIG. 2.

FIG. 4 is a cross-sectional diagram subsequent to FIG. 3.

FIG. 5 is a cross-sectional diagram showing a cross-sectional structure of a semiconductor device according to a second embodiment of the present invention.

FIG. 6 is a cross-sectional diagrams showing one example of a process of manufacturing the semiconductor device shown in FIG. 5.

FIG. 7 is a cross-sectional diagram subsequent to FIG. 6.

FIG. 8 is a cross-sectional diagram subsequent to FIG. 7.

FIG. 9 is a cross-sectional diagram subsequent to FIG. 8.

FIG. 10 is a cross-sectional diagram showing one example of a semiconductor device.

FIG. 11 is a cross-sectional diagram showing a cross-sectional configuration of the semiconductor device according to the third embodiment of the present invention.

FIG. 12 is a cross-sectional diagrams showing one example of the process of manufacturing the semiconductor device shown in FIG. 11.

FIG. 13 is a cross-sectional diagram subsequent to FIG. 12.

FIG. 14 is a cross-sectional diagram subsequent to FIG. 13.

FIG. 15 is a cross-sectional diagram subsequent to FIG. 14.

FIG. 16 is a cross-sectional diagram subsequent to FIG. 15.

FIG. 17 is a diagram showing a modified example of the gate electrode.

FIG. 18 is a cross-sectional diagram showing a cross-sectional configuration of a semiconductor device according to the fourth embodiment of the present invention.

FIG. 19 is a cross-sectional diagram of a modification of the configuration shown in FIG. 18.

### DETAILED DESCRIPTION OF THE INVENTION

An embodiment according to the present invention will be described more specifically with reference to the drawings.

### FIRST EMBODIMENT

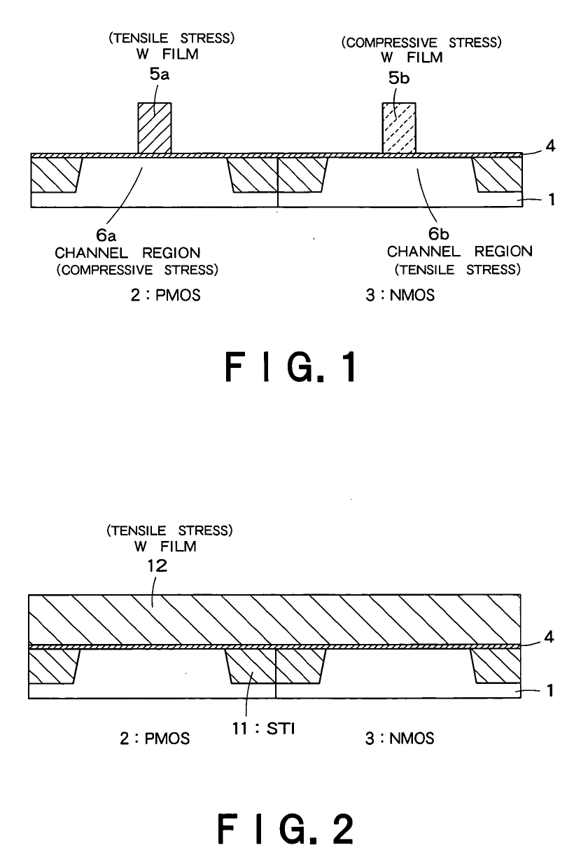

FIG. 1 is a cross-sectional diagram showing a cross-sectional configuration of a semiconductor device according to a first embodiment of the present invention. The semiconductor device shown in FIG. 1 has a PMOS transistor 2 and an NMOS transistor 3 that are adjacently formed on a silicon substrate 1. Each transistor has a gate insulation film 4 formed on the silicon substrate 1. The PMOS transistor 2 has a gate electrode 5a, and the NMOS transistor 3 has a gate electrode 5b, which are formed on the gate insulation film 4. The gate electrodes 5a and 5b are formed with tungsten (W), for example.

While the gate electrode 5a of the PMOS transistor 2 has tensile stress, the gate electrode 5b of the NMOS transistor 3 has compressive stress. Stresses in the channel regions 6a and 6b are opposite type of the stresses in the gate regions 5a and 5b, respectively. Therefore, the channel region 6a of the PMOS transistor 2 has compressive stress, and the channel region 6b of the NMOS transistor 3 has tensile stress.

In the PMOS transistor 2, the channel region 6a having compressive stress can improve mobility. Similarly, in the NMOS transistor 3, the channel 6b region having tensile stress can improve mobility. As a result, in the semiconductor device shown in FIG. 1, both the PMOS transistor 2 and the NMOS transistor 3 can improve the drive current respectively.

FIG. 2 to FIG. 4 are cross-sectional diagrams showing one example of a process of manufacturing the semiconductor device shown in FIG. 1. The process of manufacturing the semiconductor device shown in FIG. 1 is explained below with reference to these drawings. First, a silicon nitride film that becomes a mask is deposited on the silicon substrate 1 via a buffer film. Next, the silicon nitride film, the buffer film, and the silicon substrate 1 are etched to a predetermined depth, according to a pattern transfer method using a resist.

Next, after removing the resist, a silicon oxide film is deposited on the whole surface, and the surface is flattened by CMP (chemical mechanical polishing) or the like. The silicon nitride film and the buffer film are removed to form an element isolation region (STI: shallow trench isolation) 11 (FIG. 2).

A gate insulation film 4 is formed on the whole surface of the substrate (FIG. 2). The thickness of the gate insulation film 4 is 3 nanometers or smaller, for example. For the gate insulation film 4, a thermally-oxidized film that is formed by thermally oxidizing the silicon substrate 1 can be used. Alternatively, an oxynitride film or a nitride film formed by nitriding the silicon substrate 1 can be used. Alternatively, after surface processing, a high dielectric film such as a hafnium nitride film or a hafnium silicate may be formed.

Next, a metal layer for an electrode is formed on the gate insulation film 4. For example, a tungsten (W) film 12 having tensile stress is formed (FIG. 2). This film has a thickness of about 100 nanometers, for example.

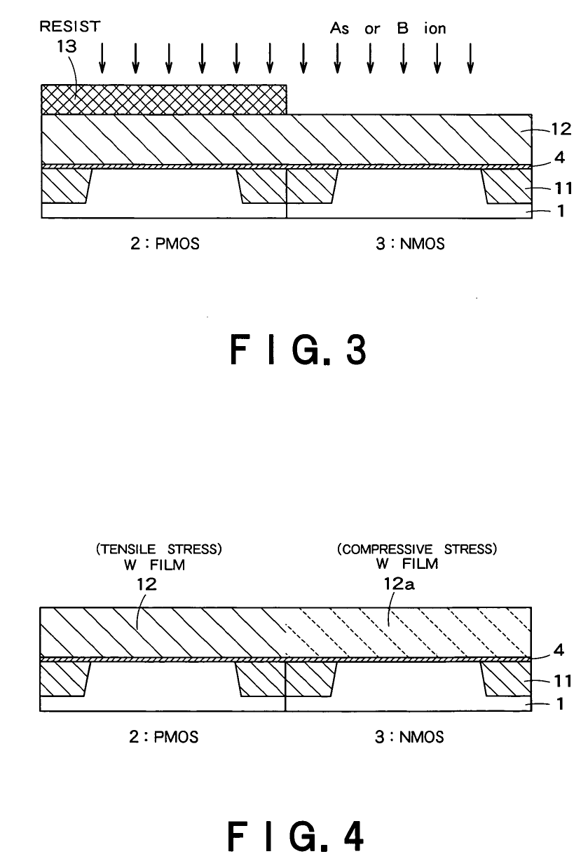

A resist 13 or the like is used to mask the region that holds tensile stress (FIG. 3). For example, the PMOS transistor region 2 is covered with the resist 13, and the tungsten film 12 in the NMOS transistor region 3 is exposed. Impurity ion such as arsenic (As) and boron (B) is injected into the tungsten film 12. A tungsten film 12a injected with the impurity ion has its tensile stress released, so that the stress of the region can be substantially disregarded, or the region changes to the region having compressive stress (FIG. 4).

The tungsten films 12 and 12a are processed by patterning and anisotropic etching like RIE (reactive ion etching) to form the gate electrodes 5a and 5b (FIG. 1). Widths of the gate electrodes 5a and 5b are determined according to needs, in a range from a fine pattern of about 10 nanometers to a large pattern of about 10 micrometers or above.

The surface of the channel disposed opposite to the gate electrode 5a of the PMOS transistor 2 made of the tungsten film 12 having tensile stress has compressive stress. The surface of the channel disposed opposite to the gate electrode 5b of the NMOS transistor 3 made of the tungsten film 12a having compressive stress has tensile stress.

After forming the configuration as shown in FIG. 1, an extension diffusion layer is formed, sidewalls of the gate electrodes 5a and 5b are formed, and source/drain diffusion layers are formed, using known techniques. Then, an inter-layer film is formed on the whole surface of the substrate, and wiring is formed using a contact process, thereby completing transistors.

As explained above, according to the first embodiment, the gate electrode 5a of the PMOS transistor 2 and the gate electrode 5b of the NMOS transistor 3 have mutually different stresses. Therefore, the stress of the channel surface of the PMOS transistor 2 and the stress of the channel surface of the NMOS transistor 3 become opposite to each other. As a result, mobility of both transistors can be improved using stresses, which increases the drive current of the transistors.

### SECOND EMBODIMENT

According to the first embodiment, the gate electrode has a single-layer structure including only a tungsten film. Therefore, an electric characteristic like a threshold voltage of a transistor also depends on the characteristic of the tungsten film. More specifically, the electric characteristic like a threshold voltage depends on a work function of a metal that is brought into contact with the gate insulation film 4. According to a second embodiment, gate electrodes are in a laminated structure, having different metal layers, one metal layer for determining an electric characteristic and the other metal layer for determining stress.

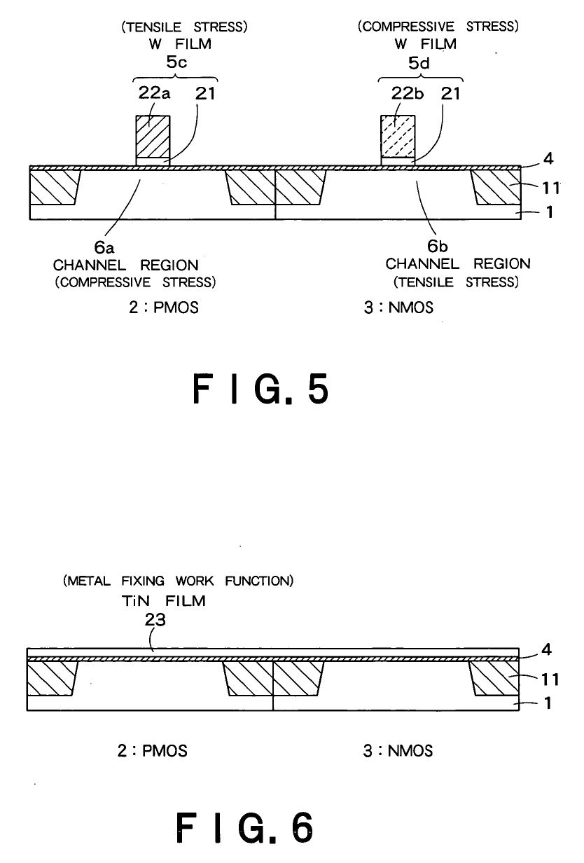

FIG. 5 is a cross-sectional diagram showing a cross-sectional structure of a semiconductor device according to a second embodiment of the present invention. According to the semiconductor device shown in FIG. 5, configurations of the gate electrodes 5c and 5d are different from those of the gate electrodes 5a and 5b of the semiconductor device shown in FIG. 1. Each of the gate electrodes 5c and 5d shown in FIG. 5 has a two-layer structure, having a first metal layer 21 formed on the gate insulation film 4 and a second metal layer formed on the first metal layer 21. The gate electrode 5c has a second metal layer 22a, and the gate electrode 5d has a second metal layer 22b.

Each first metal layer 21 is in contact with the gate insulation film 4, and determines an electric characteristic of the transistor. The first metal layer 21 is formed with titanium nitride (TiN), for example, and has a film thickness of about 5 nanometers. The second metal layers 22a and 22b determine stress on the channel surface, respectively. Each second metal layer is formed with tungsten, having a film thickness of about 100 nanometers, like the metal layer according to the first embodiment.

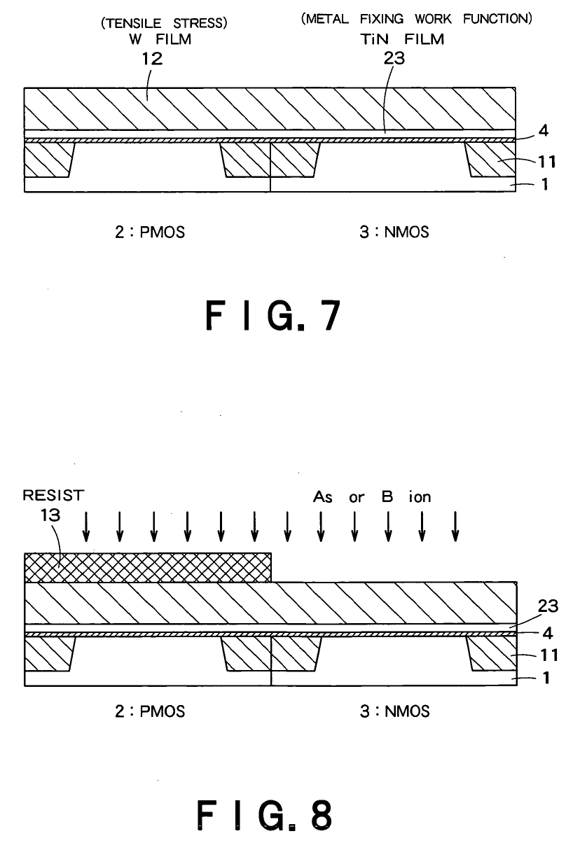

FIG. 6 to FIG. 9 are cross-sectional diagrams showing one example of a process of manufacturing the semiconductor device shown in FIG. 5. The process of manufacturing the semiconductor device shown in FIG. 5 is sequentially explained with reference to these diagrams. After the gate insulation film 4 is formed on the silicon substrate 1, titanium nitride 23 is formed on this film 4 to have a thickness of about 5 nanometers (FIG. 6). Tungsten (W) 12 is laminated on the titanium nitride 23 to have a thickness of about 100 nanometers (FIG. 7).

The subsequent steps are substantially the same as those according to the first embodiment. Briefly explaining, the formation region of the PMOS transistor 2 is masked with the resist 13, and arsenic (As) or boron (B) ion is injected into the formation region of the NMOS transistor 3, thereby releasing the tensile stress of the tungsten film 12 in the formation region of the NMOS transistor 3 or providing the tungsten film 12 with compressive stress (FIG. 8).

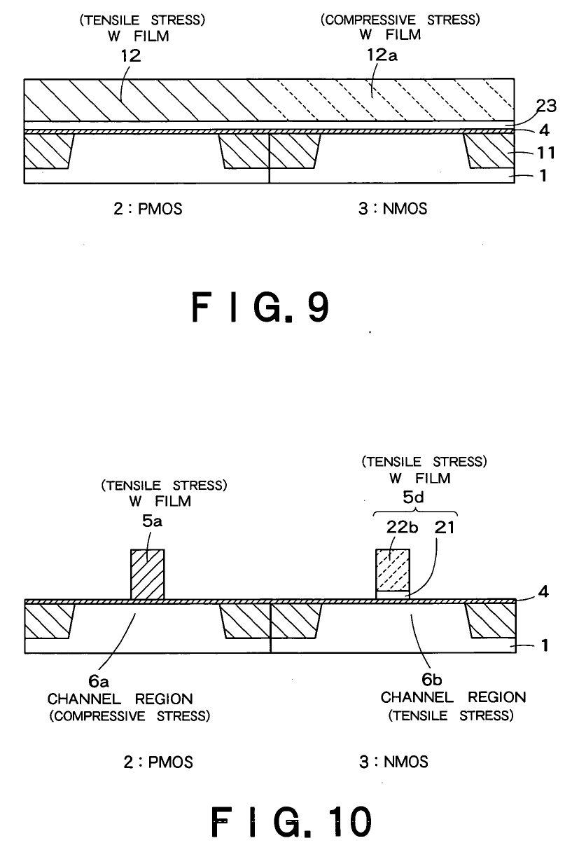

Thereafter, the resist 13 is removed (FIG. 9), and the tungsten film 12 is processed to form the gate electrodes 5c and 5d (FIG. 5).

As explained above, when the first metal layer 21 is formed with titanium nitride, electric characteristics of the transistors 2 and 3 are determined based on the characteristic of titanium nitride. More specifically, work functions of the gate electrodes 5c and 5d depend on the work function of titanium nitride, and materials of the second metal layers 22a and 22b do not influence on electric characteristics, like threshold voltages, of the transistors 2 and 3. Therefore, electric characteristics of the transistors 2 and 3 and stress on the channel surface can be controlled separately.

According to the above explanation, the second metal layers 22a and 22b that determine stresses on the channel surfaces are disposed on the upper surfaces of the first metal layers that determine electric characteristics of the transistors 2 and 3, respectively. When the first metal layer 21 and the corresponding one of the second metal layers 22a and 22b react to each other, it is preferable to dispose a reaction prevention film between the first metal layer 21 and the corresponding one of the second metal layers 22a and 22b.

According to the second embodiment, after obtaining the cross-sectional configuration as shown in FIG. 5, an extension diffusion layer is formed, sidewalls of the gate electrodes 5c and 5d are formed, and source/drain diffusion layers are formed, using known techniques. Then, an inter-layer film is formed on the whole surface of the substrate, and a wiring layer is formed using a contact process, thereby completing transistors.

The first metal layer 21 of the NMOS transistor 3 and the first metal layer 21 of the PMOS transistor 2 can be formed by using mutually different metals, thereby employing what is called a dual-metal electrode. For example, platinum silicon (PtSi) is used for the first metal layer 21 of the PMOS transistor 2, and titanium carbide (TiC) is used for the first metal layer 21 of the NMOS transistor 3. The gate electrodes 5c and 5d can be formed in laminated structure having three or more film layers, respectively. Alternatively, one of the PMOS transistor 2 and the NMOS transistors 3 can have a laminated structure, and the other transistor has a single-layer structure.

FIG. 10 is a cross-sectional diagram showing one example of a semiconductor device in which the gate electrode 5a of the PMOS transistor 2 has a single-layer structure, and the gate electrode 5d of the NMOS transistor 3 has a two-layer structure. In FIG. 10, the gate electrode 5d of the NMOS transistor 3 has the first metal layer 21 formed on the gate insulation film 4, and the second metal layer 22b formed on the first metal layer 21, like the gate electrode 5d shown in FIG. 5.

As explained above, according to the second embodiment, the first metal layers 21 that determine the electric characteristics of the corresponding transistors 2 and 3, and the second metal layers 22a and 22b that determine the stresses of the channel surfaces of the corresponding transistors 2 and 3 are used to form the gate electrodes 5a and 5d, respectively. Therefore, the electric characteristics of the transistors and the stresses of the channel surfaces can be controlled mutually independently. Consequently, transistors having excellent electric characteristics and high mobility can be formed.

### THIRD EMBODIMENT

According to a third embodiment, a semiconductor device is manufactured using a damascene process.

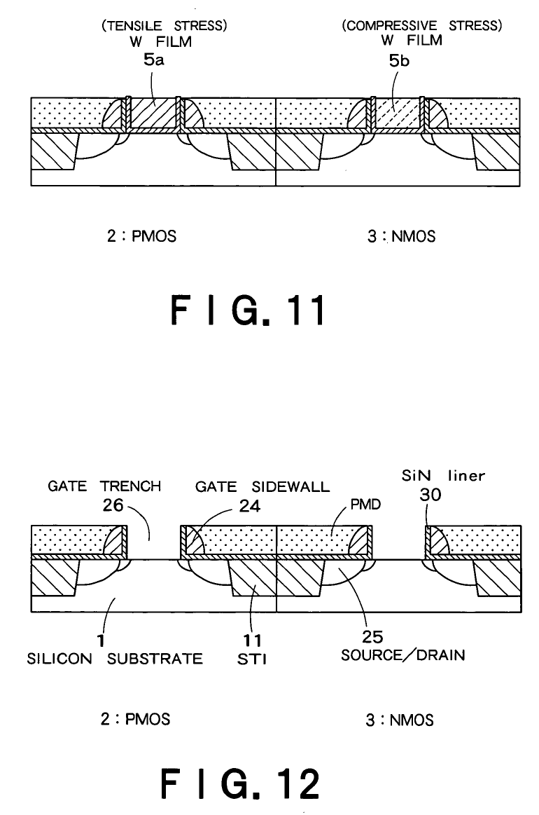

FIG. 11 is a cross-sectional diagram showing a cross-sectional configuration of the semiconductor device according to the third embodiment of the present invention. The semiconductor device shown in FIG. 11 has the PMOS transistor 2 and the NMOS transistor 3 manufactured according to the damascene process.

The gate electrode 5a of the PMOS transistor 2 and the gate electrode 5b of the NMOS transistor 3 are formed using tungsten (W) around a gate trench formed on the substrate, respectively. The gate electrode 5a of the PMOS transistor 2 has tensile stress, and the gate electrode 5b of the NMOS transistor 3 has compressive stress.

FIG. 12 to FIG. 16 are cross-sectional diagrams showing one example of the process of manufacturing the semiconductor device shown in FIG. 11. The process of manufacturing the semiconductor device shown in FIG. 11 is explained sequentially with reference to these diagrams. First, the element region and the element isolation region (STI) 11 are formed on the silicon substrate 1, and a silicon oxide film is formed on the whole surface as a buffer film, in a similar manner to that according to the first embodiment.

Next, polysilicon and a silicon nitride film 30 are formed on the whole surface of the substrate as a dummy gate film. Anisotropic etching is carried out using a resist, to form a dummy gate electrode. An extension diffusion layer region is formed, and a sidewall 24 is formed around the gate electrodes 5a and 5b, using known techniques. An impurity iron is injected to form a source/drain diffusion layer. By activating the impurity ion, a source/drain region 25 is formed. According to needs, a silicide film is formed in the source/drain region 25.

Next, for example, a silicon oxide film is deposited on the whole surface of the substrate, and the deposited silicon oxide film is etched by the CMP method or the etch-back method, thereby flattening the surface and exposing the upper surface of the dummy gate film.

The silicon nitride film and the polysilicon film are etched, and the buffer oxide film is removed with diluted hydrofuloric acid solution to expose the silicon substrate 1, thereby forming a gate trench 26 to form the gate electrodes 5a and 5b (FIG. 12).

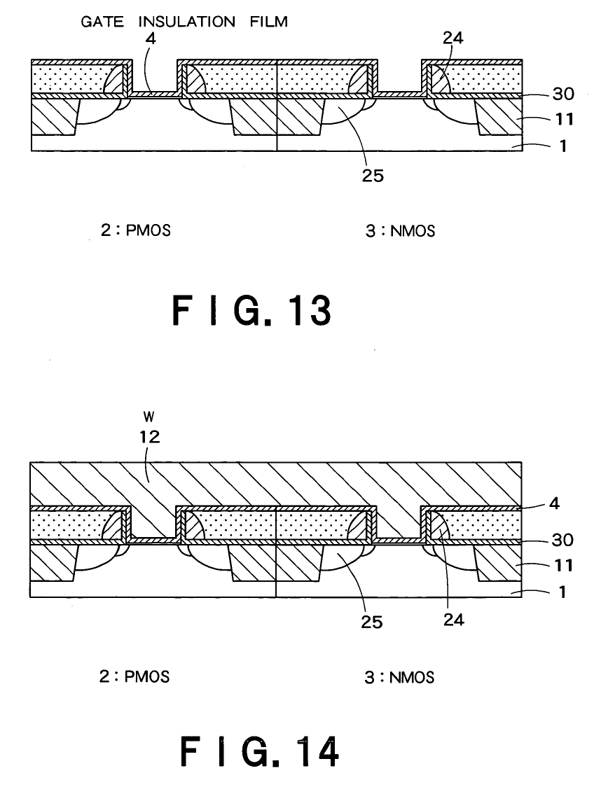

Next, the gate insulation film 4 is formed on the upper surface of the substrate including the inside of the gate trench 26 (FIG. 13). For example, the silicon substrate 1 can be oxidized, or a high dielectric film can be deposited on the whole surface of the substrate.

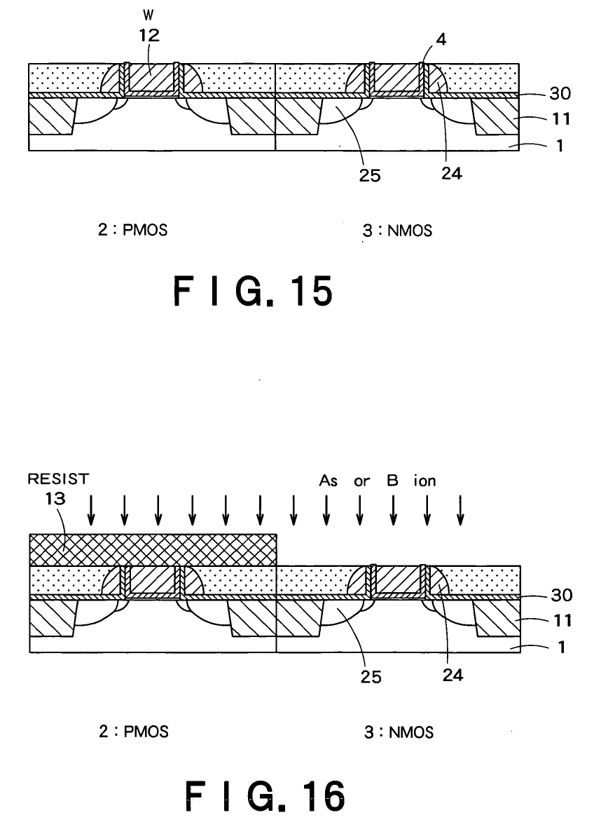

The metal layer (for example, tungsten having tensile stress) 12 that becomes the gate electrodes 5a and 5b is formed on the upper surface of the gate insulation film 4 (FIG. 14). The upper surface of the metal layer is flattened with CMP (chemical mechanical polishing) or the like, and the tungsten and the gate insulation film 4 other than the gate trench 26 are removed (FIG. 15).

The region having tensile stress (the formation region of the PMOS transistor 2) is masked with the resist 13, and impurity ion such as arsenic (As) and boron (B) is injected into the formation region of the NMOS transistor 3 (FIG. 16), in a similar manner to that according to the first embodiment. As a result, the formation region of the NMOS transistor 3 has its tensile stress released, and the stress of the region can be substantially disregarded, or the region has compressive stress (FIG. 11).

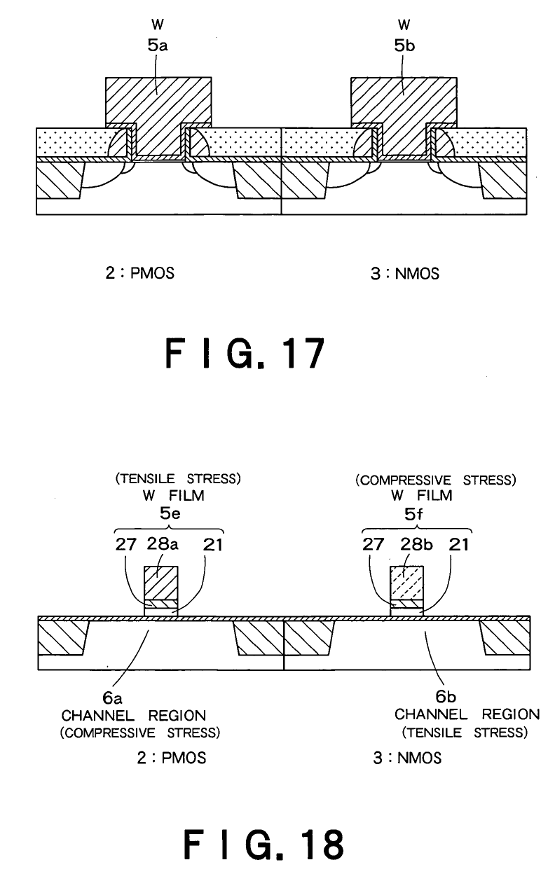

While an example of forming the gate electrodes 5a and 5b in a single-layer structure is explained above with reference to FIG. 11 to FIG. 16, the gate electrodes 5a and 5b in a laminated structure can be also formed in a similar manner to that according to the second embodiment. Alternatively, the gate electrodes 5a and 5b can be in a T-shape as shown in FIG. 17. After the process shown in FIG. 14, the gate electrodes 5a and 5b shown in FIG. 17 are formed by processing the tungsten film 12 according to patterning and reactive ion etching.

The inter-layer film and the contact are sequentially formed, in a similar manner to that applied to usual transistors.

As explained above, according to the third embodiment, when the PMOS transistor 2 and the NMOS transistor 3 are formed using the damascene process, stresses of the gate electrodes 5a and 5b of both transistors are reversed, and mobility can be improved regardless of types of transistors.

### FOURTH EMBODIMENT

According to a fourth embodiment, the gate electrodes are in a laminated structure, respectively, and a metal layer that influence stress on the channel is formed on upper layer of both the gate electrodes.

FIG. 18 is a cross-sectional diagram showing a cross-sectional configuration of a semiconductor device according to the fourth embodiment of the present invention. The semiconductor device shown in FIG. 18 has the PMOS transistor 2 and the NMOS transistor 3, and both transistors have gate electrodes 5e and 5f in a three-layer structure, respectively. Each of the gate electrodes 5e and 5f has the polysilicon layer 21 formed on the gate insulation film 4, a barrier layer 27 formed on the polysilicon layer 21, and a tungsten film formed on the barrier layer 27. The gate electrode 5e has a tungsten film 28a, and the gate electrode 5f has a tungsten film 28b.

The tungsten film as the material for the gate electrode 5e of the PMOS transistor 2 has tensile stress, and the tungsten film as the material for the gate electrode 5f of the NMOS transistor 3 has compressive stress.

A process of manufacturing the semiconductor device shown in FIG. 18 is briefly explained below. The element region and the element isolation region 11 are formed on the silicon substrate 1. The gate insulation film 4 is formed on the substrate 1, and the polysilicon layer 21 is formed on the gate insulation film 4. An impurity ion is injected into the polysilicon layer 21. Alternatively, the polysilicon layer 21 containing the impurity ion can be formed on the gate insulation film 4 in advance. The impurity ion is activated in a thermal process, and tungsten nitride (WN) is formed as the barrier layer 27 on the upper surface of the substrate. The tungsten film 12 is formed on the upper surface of the barrier layer 27.

The formation region of the PMOS transistor 2 is masked with a resist, and impurity ion such as arsenic (As) or boron (B) is injected into the formation region of the NMOS transistor 3, thereby releasing the tensile stress of the tungsten film 12 or providing the tungsten film 12 with compressive stress, in a similar manner to that according to the first to the third embodiments.

Then, in a similar manner to that according to the first to the third embodiments, the gate electrodes 5e and 5f are processed, and an extension diffusion layer is formed, gate sidewalls are formed, and source/drain diffusion layers are formed, using known techniques. Then, an inter-layer film is formed on the whole surface of the substrate, and wiring is formed using a contact process, thereby completing transistors, in a similar manner to that according to the first to the third embodiments.

The polysilicon layer 21 is used to determine work functions of the gate electrodes 5e and 5f, and electric characteristics like threshold voltages of the transistors are determined based on the work functions.

As explained above, according to the fourth embodiment, a polysilicon layer is formed as a lower layer of the gate electrodes 5e and 5f, respectively. Therefore, the electric characteristics of the transistors can be controlled. The tungsten film 12 is formed as an upper layer of the gate electrodes 5e and 5f, respectively, to control stress. Therefore, the stress of the channel surface of the PMOS transistor 2 and the stress of the channel surface of the NMOS transistor 3 can be reversed, thereby improving mobility of both transistors.

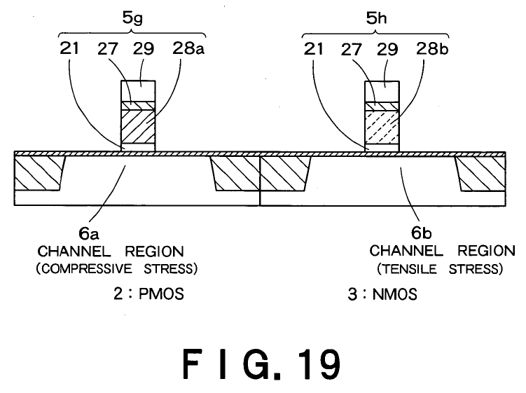

FIG. 19 is a cross-sectional diagram of a modification of the configuration shown in FIG. 18. Each of gate electrodes 5g and 5h shown in FIG. 19 has a silicide layer 29 formed on the upper surface of the tungsten film 28a or 28b via the barrier layer 27. By forming the silicide layer 29 as a top layer of the gate electrodes 5g and 5h, respectively, the total resistance of the gate electrodes 5g and 5h can be lowered.

The present invention is not limited to the above embodiments, and can be implemented by modifying the embodiments without departing from the scope of the present invention. For example, the substrate is not limited to the silicon substrate 1, and the invention can be applied to an SOI (silicon-on-insulator) substrate having a silicon active layer formed on the insulation film. While mobility is different depending on a plane direction of the substrate, a plane direction is not limited according to the present invention.

The present invention can be also applied to transistors having a three-dimensional configuration such as Fin-type channel gate electrodes 5g and 5h, in addition to a plane transistor.

In the above embodiments, while ion injection to release stress is carried out before processing the gate electrodes, ion can be injected after processing the gate electrodes. To release stress, thermal processing can be carried out in addition to the ion injection.

While tungsten has been taken up as an example of a metal having stress, silicide such as titanium silicon can be also used. Injected impurity ion is not limited to arsenic (As) or boron (B). Various other kinds of impurity ion, such as germanium (Ge) and indium (In), can be also used.

While TiN has been taken up as an example of a metal that influences the electrical characteristics, nitrides (TiN, ZrN, HfN, Ta₂N, and WN) or bromides (TiB₂, ZrB₂, HfB₂, TaB₂, MoB₂, and WB) of other metals (Ti, Zr, Hf, Ta, and W), and silicides (PtSi, and WSi) can be also used.

For the gate electrode 4, high dielectric and its oxide, oxynitride, and silicate can be also used, other than an oxidized film or hafnium.

What is claimed is:

1. A semiconductor device, comprising:
a conductive layer which includes a metal and is formed on a silicon substrate-via an insulation layer, said conductive layer being formed by implanting an impurity ion and having a stress changing region with stress different from that of the other region.

2. The semiconductor device according to claim 1, wherein said conductive layer includes:
a first conductive region in which a gate electrode of a first conductive type MOS transistor is formed; and
a second conductive region in which a gate electrode of a second conductive type MOS transistor is formed,
wherein said stress changing region is said first or second conductive region.

3. The semiconductor device according to claim 2, wherein one of said first and second conductive regions has compressive stress, and another has tensile stress.

4. A semiconductor device, comprising:
an insulation layer formed on a silicon substrate;
a first conductive layer formed on said insulation layer; and
a second conductive layer which includes a metal and is formed on said first conductive layer,
wherein said second conductive layer has a stress changing region which is formed by implanting an impurity ion and has stress different from that of the other region.

5. The semiconductor device according to claim 4, wherein said first and second conductive layers are at least a portion of a gate electrode;
said first conductive layer decides electric characteristics of said gate electrode; and
said second conductive layer controls stress of a channel region formed in said silicon substrate below said gate electrode.

6. The semiconductor device according to claim 5, wherein one of said second conductive layer and said channel region has compressive stress, and another has tensile stress.

7. The semiconductor device according to claim 4, wherein said second conductive layer includes:
a first conductive region in which a first conductive type MOS transistor is formed; and
a second conductive region in which a second conductive type MOS transistor is formed,
wherein said stress changing region is said first or second conductive region.

8. The semiconductor device according to claim 4, further comprising a barrier layer formed on said first conductive layer,
wherein said first conductive layer is a polysilicon layer.

9. The semiconductor device according to claim 4, further comprising a barrier layer formed on said second conductive layer; and
a silicide layer formed on said barrier layer.

10. The semiconductor device according to claim 4, wherein said stress changing layer has either compressive stress or tensile stress.

11. A method of fabricating a semiconductor device, comprising:
forming a conductive layer including a metal on a silicon substrate via an insulation layer; and
forming a stress changing region with stress different from that of the other region by implanting an impurity ion to a portion of said conductive layer.

12. The method of fabricating the semiconductor device according to claim 11, wherein a first conductive region in which a gate electrode of a first conductive type MOS transistor and a second conductive region in which a gate electrode of a second conductive type MOS transistor are formed in said conductive layer; and
said stress changing region is said first or second conductive region.

13. The method of fabricating the semiconductor device according to claim 12, wherein one of said first and second conductive regions has compressive stress and another has tensile stress.

14. The method of fabricating the semiconductor device according to claim 11, wherein said conductive layer has first and second conductive layers;
said insulation layer is formed on said silicon substrate;
said first conductive layer is formed on said insulation layer;
said second conductive layer includes a metal, is formed on said first conductive layer, and has a stress changing region with stress different from that of the other region, said stress changing region being formed by implanting an impurity ion.

15. The method of fabricating the semiconductor device according to claim 14, wherein said first and second conductive layers are at least a portion of a gate electrode;
said first conductive layer fixes a work function of said gate electrode; and
said second conductive layer controls stress in a channel region formed in said silicon substrate below said gate electrode.

16. The method of fabricating the semiconductor device according to claim 15, wherein one of said second conductive layer and said channel region has compressive stress and another has tensile stress.

17. The method of fabricating the semiconductor device according to claim 14, wherein a first conductive region in which a first conductive type MOS transistor is formed and a second conductive region in which a second conductive type MOS transistor is formed are provided with said second conductive layer; and
said stress changing region is said first or second conductive region.

18. The method of fabricating the semiconductor device according to claim 14, wherein a barrier layer is formed between said first and second conductive layers; and
said first conductive layer is a polysilicon layer.

19. The method of fabricating the semiconductor device according to claim 14, wherein a barrier layer is formed on said second conductive layer; and
a silicide layer is formed on said barrier layer.

20. The method of fabricating the semiconductor device according to claim 14, wherein said first and second conductive layers are formed by using a damocene process.
